(19) United States
(12) Patent Application Publication
(10) Pub. No.: US 2015/0225231 A1
(43) Pub. Date: Aug. 13, 2015

(54) MEMS DEVICE AND METHOD FOR PRODUCING AN MEMS DEVICE OPERATING WITH ACOUSTIC WAVES

(71) Applicant: EPCOS AG, Munich (DE)

(72) Inventor: Gudrun Henn, Ebenhausen (DE)

(73) Assignee: EPCOS AG, Munich (DE)

(21) Appl. No.: 14/424,992

(22) PCT Filed: Jul. 31, 2013
(86) PCT No.: PCT/EP2013/066109

§ 371 Date: Feb. 27, 2015

(30) Foreign Application Priority Data
Aug. 31, 2012 (DE) 10 2012 108 106.9

(51) Int. Cl. B81C 1/00; H01L 41/053; B81B 7/00

(52) U.S. Cl. CPC B81C 1/00682; B81B 7/0067; H01L 41/053

(57) ABSTRACT

The present invention relates to a method for producing an MEMS device (1) operating with acoustic waves. The method comprises the steps of producing an MEMS component (2) operating with acoustic waves on a substrate (3), encapsulating the component (2) with a housing layer (10), wherein the housing layer (10) is transmissive to electromagnetic radiation (14) in a wavelength range, and trimming the component (2) by irradiating the component (2) with electromagnetic radiation (14) having a wavelength lying in the wavelength range in which the housing layer (10) is transmissive to the electromagnetic radiation (14). Furthermore, the invention relates to an MEMS device (1) comprising a housing layer (10) transmissive to electromagnetic radiation (14) in the wavelength range.

An MEMS device and a method for producing an MEMS device operating with acoustic waves are specified. The MEMS device can comprise a component which operates with bulk acoustic waves (BAW) or with surface acoustic waves (SAW).

Housings of MEMS components, such as, for example, surface-acoustic-wave-based or bulk-acoustic-wave-based devices, generally require cavities. Once the component has been encapsulated in such a housing, then it is no longer possible to process the component and adapt it in terms of its acoustic properties, for example.

U.S. Pat. No. 7,170,369 B2 describes a method for trimming a mechanical resonator.

It is an object of the present invention to provide a method which makes it possible, in the case of an MEMS device, to minimize the deviation of at least one acoustic property from a previously specified value. The object is achieved by means of the method according to claim 1. Furthermore, the further independent claim specifies a device which can be produced for example in accordance with this method.

A method for producing an MEMS device operating with acoustic waves is specified. The method comprises the following steps:

producing an MEMS component operating with acoustic waves on a substrate,

encapsulating the component with a housing layer, wherein the encapsulation layer is transmissive to electromagnetic radiation in a wavelength range, and

trimming the component by irradiating the component with electromagnetic radiation having a wavelength lying in the wavelength range in which the housing layer is transmissive to the electromagnetic radiation.

In this case, trimming is defined as the targeted variation of an acoustic property of a component.

When producing a component, it is often not possible to prevent certain tolerances in production. Said tolerances can have a considerable influence on the acoustic properties of a component operating with acoustic waves. By way of example, said tolerances can have the effect that the resonant frequency deviates from a prespecified desired value for the component.

The method specified here makes it possible to minimize these tolerances by virtue of the component being trimmed after encapsulation.

In particular, the method step of encapsulating the component can also result in an undesirable variation of the acoustic properties. It is only the use of housings which are transmissive to the electromagnetic radiation having a specific wavelength that makes it possible for the component still to be trimmed even after its encapsulation.

Hereinafter, various methods are specified with which a trimming of the component is performed in each case by irradiating the component with electromagnetic radiation. These include for example removing material either in a resonance region or a passive region, increasing the density of a material on account of irradiation, reducing the finger width in the case of a surface-acoustic-wave-based component, or initiating the combination of the surface of the component with molecules of a gas atmosphere.

The housing layer described here either can be totally transmissive to the electromagnetic radiation in the corresponding wavelength range or can have at least one region in which it is transmissive to the electromagnetic radiation in the corresponding wavelength range. Furthermore, the housing layer can consist of a plurality of partial layers. In particular, the housing layer can have a structured first stabilizing layer and an encapsulation layer. The structured first stabilizing layer and the encapsulation layer in turn either can be totally transmissive to the electromagnetic radiation in the corresponding wavelength range or can each have at least one region in which they are transmissive to the electromagnetic radiation in the corresponding wavelength range.

The structured first stabilizing layer of the housing layer can be formed from a monoatomic carbon layer, graphene, and/or nanotubes. Alternatively, the structured first stabilizing layer can comprise oxides or nitrides. The encapsulation layer can have a plurality of partial layers. In this case, at least some of the partial layers can also be embodied as conductive and thus radio-frequency-shielding. Layers of the encapsulation layer can comprise an epoxy material applied by means of a printing method or, if they are intended to be conductive, can consist of metals. Furthermore, the encapsulation layer can comprise polymers.

Furthermore, the method can comprise the step of measuring at least one acoustic property of the component after encapsulating the component. The acoustic property can be for example the resonant frequency of a resonator. Alternatively, the acoustic property can also be a bandwidth or an edge steepness of a filter. An acoustic property of a circuit comprising a plurality of components could also be measured.

Furthermore, the component, depending on the measured value of the acoustic property, can be subsequently irradiated with electromagnetic radiation in such a way that the acoustic property of the component is adapted to a desired value specified for the device. Accordingly, an appropriate trimming method is selected depending on the measured deviation of the acoustic property from the predefined desired value. By way of example, a different region of the component can be selected for the irradiation depending on the measured deviation.

Furthermore, the MEMS component can have a resonator having a resonance region, which determines the acoustic properties of the resonator, and a passive region, which does not directly determine the acoustic properties. In the case of a bulk-acoustic-wave-based resonator, the resonance region is defined by the fact that two electrodes, between which a piezoelectric layer is arranged, overlap in the direction of propagation of the bulk acoustic wave. In the case of a surface-acoustic-wave-based resonator, the resonance region is defined by the fact that the electrode fingers of two electrodes arranged on a piezoelectric substrate overlap in the direction of propagation of the surface acoustic wave. The passive region is defined here in each case by the fact that no overlap of the electrodes or electrode fingers is present, such that no acoustic wave is excited in the passive region.

If the measurement described above then reveals that the resonant frequency of the resonator is lower than a desired value specified for the device, then the resonance region of the resonator is irradiated with electromagnetic radiation. Material in the resonance region is removed as a result of the irradiation with electromagnetic radiation and deposits uniformly on the entire surface of the component, such that the thickness of the resonator is reduced in the resonance region. In the case of a bulk-acoustic-wave-based resonator, a reduced thickness leads to an increase in the resonant frequency and accordingly to a trimming of the resonator.

If the measurement described above reveals that the resonant frequency of the resonator is higher than a desired value specified for the device, then the passive region of the resonator is irradiated with electromagnetic radiation. In this case, material in the passive region is removed as a result of the irradiation with electromagnetic radiation and deposits uniformly on the entire surface of the component, such that the thickness of the resonator is increased in the resonance region. This leads directly to a reduction of the resonant frequency.

The method described here makes it possible accordingly both to increase and to reduce the resonant frequency of a resonator. Trimming is thus possible independently of whether the resonant frequency deviates upward or downward from the prespecified desired value.

However, other possibilities of trimming by irradiation with electromagnetic radiation are also possible. They can be performed as an alternative or in addition to the removal of material in a specific region.

The component can be encapsulated in a vacuum. However, the vacuum will not be a perfect vacuum, but rather will have a certain residual pressure. The component can also be encapsulated in a targeted manner in a gas atmosphere. Very low vacuum-like pressures are preferably chosen here as well.

If a component encapsulated in a gas atmosphere is then irradiated with electromagnetic radiation, the material of the surface of the component is heated as a result of the irradiation with electromagnetic radiation. In this case, the material of the surface can combine with the gas atoms of the gas atmosphere. The gas atmosphere can be, for example, an atmosphere comprising N₂ or an oxygen atmosphere.

The chemical combination of the surface with the gas molecules results in turn in the trimming of at least one acoustic property of the component. By way of example, the combination can lead to a variation of the density of the surface, as a result of which the propagation velocity of acoustic waves is varied.

In particular, the gas can react with the surface and modify the latter in the process. Alternatively, the irradiation can result in a deposition of the gas molecules on the surface. In both cases, the surface is thus altered in a targeted manner, such that the component is trimmed.

If the component is encapsulated in an atmosphere comprising N₂, then it can be trimmed by reactive nitriding of the surface of the component by irradiation with the electromagnetic radiation. If the component is encapsulated in an oxygen atmosphere, then it can be trimmed by oxidation of the surface of the component by irradiation with the electromagnetic radiation. Both nitriding and oxidation of the surface can be initiated in a very targeted manner, such that the relevant acoustic property, for example the resonant frequency, can be set very accurately in this case.

Furthermore, the method can comprise the steps of applying a trimming layer on the surface of the component prior to encapsulating, and trimming the component by increasing the density of the trimming layer by irradiating with electromagnetic radiation. The trimming layer can be a partial layer of a cover layer which covers the surface of the component. The trimming layer can for example comprise aluminum or consist of aluminum. As a result of the irradiation, the aluminum in the trimming layer can be oxidized to form Al₂O₃, as a result of which the density of the trimming layer is increased.

The trimming layer can be applied by chemical vapor deposition (CVD). The thickness of a layer applied by means of chemical vapor deposition can be set very accurately.

A femtosecond laser can be used for irradiating the component. The radiation from this laser is emitted in very short pulses, such that heat is fed to the component in each case only to a small extent. Destruction of the component as a result of thermal effects can thereby be avoided.

In some trimming methods, however, the heating of the surface of the component to a certain extent is also desirable in order, for example, to excite combination of the surface with gas molecules. In this case, it can be expedient to use a laser which supplies somewhat longer and hence higher-energy pulses. By way of example, a picosecond laser could be used.

If the component has a resonator operating with surface acoustic waves and having a metallization in the form of a finger structure comprising electrode fingers, then the device can be irradiated in such a way that the width of an electrode finger is reduced as a result of the irradiation with electromagnetic radiation. In particular, the width of individual electrode fingers can be reduced in order to compensate for production tolerances during production. If the material of the electrode finger is removed only on one side of the electrode finger, then as a result the finger center shifts, which crucially influences the surface acoustic wave excited by the electrode finger.

In particular, the resonant frequency of a surface-acoustic-wave-based resonator is defined by the center-to-center distance between the respectively adjacent electrode fingers. Small production tolerances in the center-to-center distance can be corrected by targeted removal of material at one side of an electrode finger, such that the resonant frequency can be trimmed in this way.

Furthermore, a plurality of resonators can be produced on the substrate, which resonators are interconnected to form a duplexer. The resonators can be jointly encapsulated. After encapsulation, the resonators can be successively trimmed by irradiation with electromagnetic radiation by means of the method described above. In this case, then, what is optimized is not necessarily the acoustic properties of an individual resonator, but rather an acoustic property of the filter circuit, for example the bandwidth or the edge steepness.

In the method specified, the MEMS component is preferably encapsulated in a thin film package, the layer construction of which was produced directly on the substrate using thin film methods. Thin film package is understood to mean a layer sequence having a plurality of layers arranged one above another. Accordingly, the housing layer is preferably such a layer sequence.

The thin film package is transmissive to the electromagnetic radiation emitted by the laser and is accordingly especially suitable for the method specified here. It is only the use of a housing layer which is transmissive to the electromagnetic radiation in the corresponding wavelength range that enables trimming after the encapsulation of the component.

If the housing layer is produced as a layer construction directly on the substrate using thin film methods, then the housing layer has a small height, such that the device is distinguished by a very high degree of miniaturization.

Furthermore, the invention relates to an MEMS device operating with acoustic waves and comprising an MEMS component on a substrate and a housing layer. The housing layer encapsulates the MEMS component and is transmissive to electromagnetic radiation in a wavelength range.

The MEMS device can be produced for example according to the method according to claim 1. Accordingly, the abovementioned structural and functional features disclosed in association with the method can also apply to the device individually or in combination.

Furthermore, the surface of the component can have at least one local region having an increased density that is higher than the density of the rest of the surface of the component. In particular, the region having an increased density can be produced by irradiation by means of a laser in accordance with the trimming method described above. Accordingly, this region can be nitrided or oxidized, for example. Furthermore, gas molecules might have been deposited into this region.

The invention is explained in greater detail on the basis of the figures and exemplary embodiments.

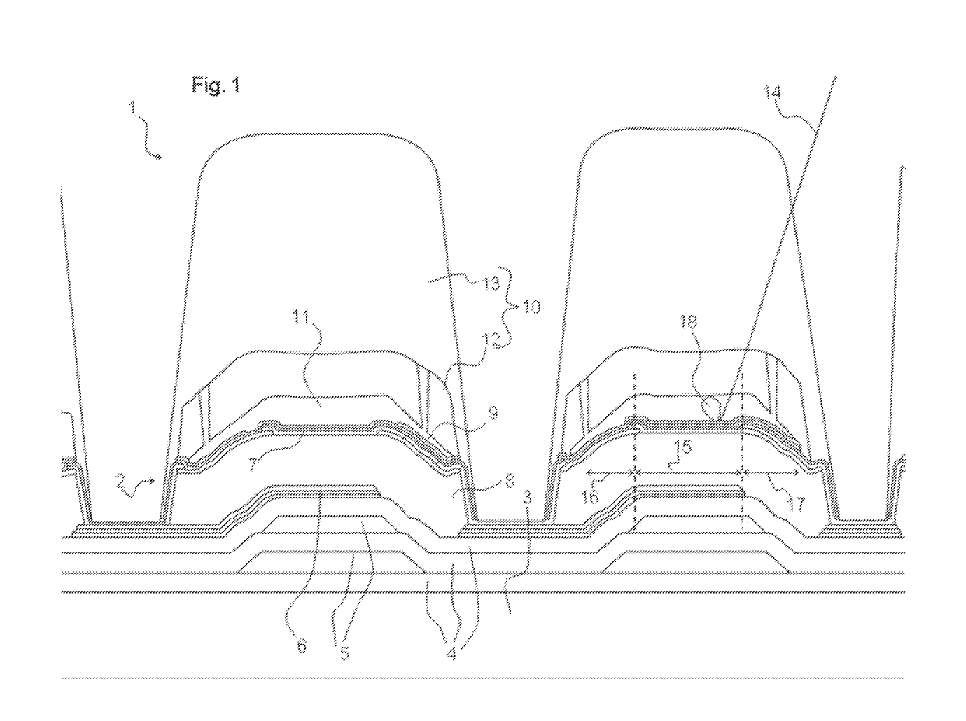

FIG. 1 shows the schematic side view of one embodiment of the electronic component.

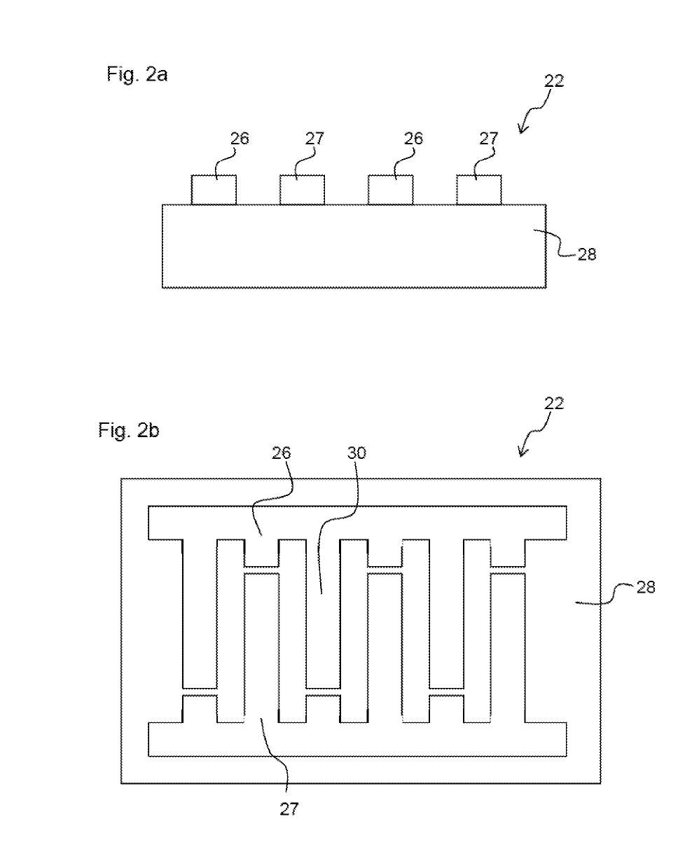

FIG. 2a shows the schematic side view of a further embodiment of the electronic component.

FIG. 2b shows a schematic plan view of the electronic component in accordance with FIG. 2a.

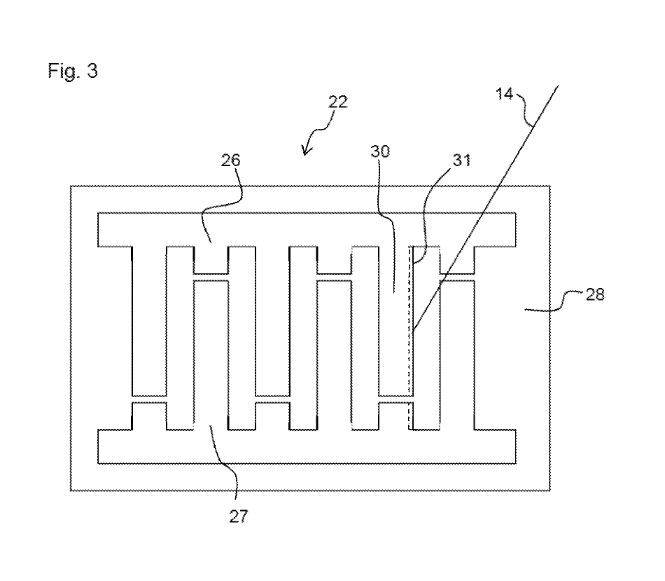

FIG. 3 shows the schematic side view of the component illustrated in FIGS. 2a and 2b during irradiation with a laser.

The present invention relates to a method for producing an MEMS device 1 operating with acoustic waves, wherein the MEMS device 1 is trimmed during production. Trimming here denotes the targeted variation of at least one acoustic property of the device 1. In this case, the acoustic property is adapted to a previously specified desired value. The acoustic property can be, for example, the resonant frequency of a resonator. The method also makes it possible to trim the acoustic properties of a circuit comprising a plurality of components, for example the bandwidth and/or the edge steepness of filter circuits.

In accordance with a first exemplary embodiment, the MEMS device 1 comprises a bulk-acoustic-wave-based electroacoustic MEMS component 2. In particular, the MEMS device 1 can comprise an MEMS resonator operating with bulk acoustic waves.

FIG. 1 shows the schematic side view of the MEMS device 1 in accordance with this first exemplary embodiment, wherein the MEMS device 1 comprises an MEMS resonator operating with bulk acoustic waves. FIG. 1 shows two MEMS devices 1, each comprising an MEMS resonator operating with bulk acoustic waves. The devices 1 shown in FIG. 1 can be singulated in a further method step.

The MEMS resonator operating with bulk acoustic waves has a substrate 3, a plurality of first reflective layers 4, a plurality of second reflective layers 5, a first electrode 6, a second electrode 7 and a piezoelectric layer 8. The first and second reflective layers 4, 5 are arranged alternately one above another. The reflective layers 4, 5 constitute Bragg mirrors, wherein the first reflective layer 4 has a low acoustic impedance and the second reflective layer 5 has a high acoustic impedance.

The first reflective layer 4 can contain SiO₂, for example, and the second reflective layer 5 tungsten. Reflective layers 4, 5 arranged in this way have a high reflectivity both for longitudinal waves and for shear waves. Therefore, these waves can be reflected so as to be guided back into the piezoelectric layer 8.

The substrate 3 can comprise Si or SiO₂, for example. The actual resonator is situated on the reflective layers 4, 5 and comprises the first electrode 6, the second electrode 7 and the piezoelectric layer 8. The piezoelectric layer 8 can contain AlN, for example, and the two electrodes 6, 7 can comprise metals such as Ti, Mo, mixtures of Ti and Mo, Pt, Ru, W, Al, Cu and mixtures of Al and Cu. The electrodes 6, 7 can also contain a plurality of partial layers stacked one above another, wherein each partial layer contains a different material that can be selected from those enumerated above. By way of example, an electrode 6, 7 can have the sandwich structure Ti, Al/Cu, W. A further possible sandwich structure has the construction Mo, Ti/Mo, Ru.

Furthermore, a cover layer 9 is applied on the arrangement shown in FIG. 1 and covers the resonator. The cover layer 9 can consist of a plurality of layers. The cover layer 9 can comprise a trimming layer and/or a passivation layer and/or a tuning layer. The passivation layer can comprise an oxide layer. Furthermore, at least some of the layers of the cover layer 9 can be applied by chemical vapor deposition (CVD).

Furthermore, a housing layer 10 having a cavity is applied above the component. FIG. 1 shows a cavity 11 above the MEMS component 2, a structured first stabilizing layer 12 above the cavity 11, and an encapsulation layer 13 above the first layer 12. The structured first stabilizing layer 12 can be formed from a monoatomic carbon layer, graphene, and/or nanotubes. Alternatively, the structured first stabilizing layer 12 can comprise oxides or nitrides. On account of its high mechanical stability, it can stably span the cavity 11 and at the same time bear the encapsulation layer 13.

The encapsulation layer 13 brings about a further stabilization and seals the MEMS component 2 against moisture. The encapsulation layer 13 can have a plurality of partial layers. At least some of the partial layers in this case can also be embodied as conductive and hence radio-frequency-shielding. Layers of the encapsulation layer 13 can comprise an epoxy material applied by means of a printing method or, if they are intended to be conductive, can consist of metals. Furthermore, the encapsulation layer 13 can comprise polymers.

Both the structured first stabilizing layer 12 and the encapsulation layer 13 are transmissive to the electromagnetic radiation 14 of a laser used—as will be discussed below—for trimming the device 2. It is only the use of this housing layer 10, which is also designated as thin film package, for encapsulation that makes it possible for the device 1 still to be trimmed even after its encapsulation, since the layers of the thin film package are transparent to the electromagnetic radiation of the laser.

After the encapsulation of the MEMS component 2 in the thin film package, trimming of the component 2 can be performed. After encapsulation, firstly an acoustic property of the device 2 is measured. The acoustic property is, for example, the resonant frequency of the resonator or the bandwidth of a circuit comprising the resonator.

In order to trim the resonator after encapsulation, the resonator is irradiated with electromagnetic radiation 14. For this purpose, the resonator is preferably irradiated by means of a femtosecond laser which makes it possible to direct very short and locally accurately fixed pulses of electromagnetic radiation 14 onto the resonator.

The resonator operating with bulk acoustic waves has an active resonance region 15 and passive regions 16, 17, which do not directly determine the acoustic properties of the resonator. The active resonance region 15 is the region in which the first and second electrodes 6, 7 overlap.

The passive regions 16, 17 laterally adjoin the active resonance region. In a first passive region 16, the component 2 comprises a layer stack, comprising the cover layer 9, the second electrode 7 and the piezoelectric layer 8, but not the first electrode 6. Therefore, since no first electrode 6 is situated opposite the second electrode 7 here, no bulk acoustic waves can be excited in said first passive region 16. In a second passive region 17, the component 2 comprises a layer stack, comprising the cover layer 9, the piezoelectric layer 8 and the first electrode 6, but not the second electrode 7. No bulk acoustic waves can be excited in the second passive region 17 either.

Therefore, the resonant frequency of the resonator is substantially determined by the active resonance region 15. The thickness of the resonator in the active resonance region 15 is crucial for the resonant frequency. Furthermore, the resonant frequency is also influenced by the material of the layers in the active resonance region 15, in particular by the density of the material, since the propagation velocity of the bulk acoustic waves is influenced by the density.

After encapsulation, firstly the resonant frequency of the resonator is determined. On account of virtually unavoidable production tolerances, it can be assumed that the resonant frequency will deviate slightly from a specified desired value for the device 1. This deviation can then subsequently be corrected by the trimming.

If the resonant frequency of the resonator operating with bulk acoustic waves is less than the specified desired value, then the laser is directed onto the resonance region 15 of the resonator. This case is illustrated in the right-hand device in FIG. 1.

If the resonance region is irradiated with electromagnetic radiation 14, then material is removed from the resonance region 15. The material removed in this way is distributed homogeneously in the entire component 2. In particular, the material locally removed by the laser radiation forms a plasma cloud 18, which propagates within the cavity 11. Accordingly, the material removed in the active resonance region 15 deposits uniformly in the resonance region 15 and in the passive regions 16, 17. Accordingly, the thickness of the resonator is reduced in the active resonance region 15. A reduced thickness corresponds to an increase in the resonant frequency of the resonator.

Conversely, if it is ascertained during the measurement that the resonant frequency is higher than the specified desired value, then the passive region 16, 17 of the component 2 is irradiated by means of the laser. Material in the passive region 16, 17 is then removed. This material in turn firstly forms a plasma cloud, which is then distributed homogeneously on the entire area within the cavity 11 and is thus also deposited partly on the resonance region 15. As a result, the thickness of the resonance region 15 of the resonator is increased. Accordingly, the resonant frequency shifts toward a lower frequency and thus approaches the prespecified desired frequency.

The irradiation is carried out by means of a femtosecond laser. The radiation of this laser is emitted in very short pulses, such that heat is fed to the device 1 in each case only to a small extent. As a result, destruction of the device 1 by thermal effects can be avoided.

In particular, the femtosecond laser can be focused in such a way that its focusing plane lies on the surface of the component 2, while said laser is unfocused in the region of the housing layer 10. What is achieved as a result is that only a minimum value of electromagnetic energy becomes free in the region of the housing layer 10, while the maximum electromagnetic energy is liberated near the surface of the component 2.

Other types of trimming by means of irradiation with electromagnetic radiation 14 are also possible. In the cavity 11, the component 2 can be encapsulated in a gas atmosphere. The gas atmosphere can be, for example, an atmosphere comprising N₂ or an oxygen atmosphere. As a result of the irradiation with electromagnetic radiation 14, the surface of the component 2 is then heated, such that the surface combines with the gas atoms of the gas atmosphere and a modification of the surface occurs. Alternatively, a gas deposition on the surface can be initiated by the radiation from the laser.

Since the heating of the surface is now intended to be brought about in a controlled manner, a picosecond laser can be used instead of a femtosecond laser. The picosecond laser supplies somewhat longer pulses which can heat the surface in a targeted manner, without leading here to damage to the component 2 as a result of thermal effects.

As a result of this alteration of the surface, an acoustic property of the resonator can be trimmed in a targeted manner. In particular, the topmost layer of the cover layer 9 can be a trimming layer. The density of the trimming layer is increased as a result of the irradiation by means of the laser. By way of example, the cover layer 9 as the topmost layer of the resonator can comprise aluminum that is converted into Al₂O₃ by the laser irradiation. Aluminum oxide has a higher density than aluminum, such that the density of the cover layer 9 is increased by the irradiation. The increase in the density results in a reduction of the propagation velocity of the bulk acoustic waves, such that the resonant frequency of the device 2 is reduced.

It is therefore possible firstly to construct the device 1 with a somewhat excessively high resonant frequency and then to set the latter to the prespecified desired value in a targeted manner by irradiation and conversion of the trimming layer.

Furthermore, in a device 1 a plurality of resonators operating with bulk acoustic waves can be interconnected with one another. The resonators can be interconnected for example to form a filter or duplexer. As a result of targeted trimming of each individual one of the resonators interconnected with one another, the resonant frequency of each individual resonator can be corrected independently. If the individual resonators are trimmed in terms of their resonant frequency, then the bandwidth and/or the edge steepness of the duplexer can be trimmed as a result.

In accordance with a second exemplary embodiment, the MEMS device 1 comprises a surface-acoustic-wave-based electroacoustic MEMS component 22. In particular, the MEMS device 22 can comprise an MEMS resonator operating with surface acoustic waves.

FIG. 2a shows the schematic side view of a surface-acoustic-wave-based component 22. The latter comprises the piezoelectric layer 28, a first electrode 26 and a second electrode 27.

FIG. 2b shows such a component 22 in a schematic plan view. With reference to this figure it is evident that the first electrode 26 and the second electrode 27 in each case have a comb-like structure, wherein each comb alternately has a short and a long electrode finger 30. The electrode fingers 30 of the different combs are arranged on the piezoelectric layer alternately in succession along the longitudinal axis of the piezoelectric layer 28. This is also evident in the schematic side view in FIG. 2a. Therefore, electromagnetic waves form between the individual electrode fingers 30 of the electrodes 26, 27, which electromagnetic waves can be converted into mechanical waves, and vice versa, by the piezoelectric layer 28.

The surface-acoustic-wave-based component 22 is also encapsulated by a housing layer 10. The housing layer 10 is a thin film package. The housing layer 10 has the same structural and functional features as the housing layer which encapsulates the bulk-acoustic-wave-based component 2 of the first exemplary embodiment. In particular, the housing layer 10 is a thin film package having a multilayer construction comprising a structured first stabilizing layer 12 above the cavity 11 and an encapsulation layer 13 above the first layer 12.

The resonator operating with surface acoustic waves can also be trimmed after encapsulation. For this purpose, at least one acoustic property, for example the resonant frequency, is measured and a possible deviation from a previously specified desired value is determined. The trimming methods already discussed in association with the resonator operating with bulk acoustic waves can at least in part also be applied to a resonator operating with surface acoustic waves.

In this regard, the resonator operating with surface acoustic waves can have a cover layer 9 above the electrodes, the density of which cover layer is increased by irradiation by means of the laser. As a result, the propagation velocity of the surface acoustic wave is reduced and, therefore, the resonant frequency of the resonator is likewise reduced.

FIG. 3 furthermore shows that alternatively the width of an electrode finger 30 can be reduced by material being removed on a side area 31 of the electrode finger 30. In this respect, FIG. 3 shows a surface-acoustic-wave-based component 22 in plan view. Width here denotes the extent of the electrode finger 30 in the direction in which the surface acoustic wave propagates. The side area 31 of the electrode finger 30 is perpendicular to the substrate and the surface normal of the side area 31 is parallel to the direction of propagation of the surface acoustic wave.

If, as indicated by a dashed line in FIG. 3, material is removed only on a side area 31 of the electrode finger 30, then the center-to-center distance between two adjacent electrode fingers 30 changes. Said center-to-center distance determines the resonant frequency of the resonator operating with surface acoustic waves. Possible fault tolerances during production can subsequently be corrected in this way, such that the resonant frequency is set as accurately as possible to the previously determined desired value.

The resonator operating with surface acoustic waves can also be encapsulated in a gas atmosphere, for example an atmosphere comprising N₂ or an oxygen atmosphere. As a result of the irradiation with electromagnetic radiation 14, the surface of the resonator reacts with the gas molecules of the gas atmosphere and a deposition of the gas molecules or a modification of the surface occurs. In this way, the resonant frequency can likewise be varied in a targeted manner.

Furthermore, in a device a plurality of resonators operating with surface acoustic waves can be interconnected with one another. The resonators can be interconnected for example to form a filter or duplexer. As a result of targeted trimming of each individual one of the resonators interconnected with one another, the bandwidth and/or the edge steepness of the duplexer can be trimmed.

Furthermore, circuits are possible in which bulk-acoustic-wave-based and surface-acoustic-wave-based resonators are combined with one another. Here, too, each of the resonators can be trimmed successively by irradiation with electromagnetic radiation 14. As a result, the resonant frequency of each individual resonator can be trimmed, such that bandwidth and/or edge steepness of the circuit are/is trimmed.

It is crucial for the components 2 to be encapsulated in a thin film package, since the latter is transmissive to electromagnetic radiation 14 in the wavelength range of the laser used. In this way, trimming after encapsulation is made possible for the first time for MEMS device 2 operating with acoustic waves.

### LIST OF REFERENCE SIGNS

1 MEMS device
2 MEMS component
3 substrate
4 first reflective layer
5 second reflective layer
6 first electrode
7 second electrode
8 piezoelectric substrate
9 cover layer
10 housing layer
11 cavity
12 structured first stabilizing layer
13 encapsulation layer
14 electromagnetic radiation
15 active resonance region
16 first passive region
17 second passive region
18 plasma cloud
22 MEMS component
26 first electrode
27 second electrode
28 piezoelectric substrate
30 electrode finger
31 side area

1. A method for producing an MEMS device (1) operating with acoustic waves, comprising the following steps:
producing an MEMS component (2) operating with acoustic waves on a substrate (3),
encapsulating the component (2) with a housing layer (10), wherein the housing layer (10) is transmissive to electromagnetic radiation (14) in a wavelength range,
trimming the component (2) by irradiating the component (2) with electromagnetic radiation (14) having a wavelength lying in the wavelength range in which the housing layer (10) is transmissive to the electromagnetic radiation (14).

2. The method according to claim 1,
furthermore comprising the following step:
measuring at least one acoustic property of the component (2) after encapsulating the component (2), wherein the component (2), depending on the measured value of the acoustic property, is subsequently irradiated with electromagnetic radiation (14) in such a way that the acoustic property of the component (2) is adapted to a desired value specified for the device (1).

3. The method according to either of the preceding claims,
wherein the MEMS component (2) has a resonator having a resonance region (15), which determines the acoustic properties of the resonator, and a passive region (16, 17), which does not directly determine the acoustic properties, wherein the resonance region (15) of the resonator is irradiated with electromagnetic radiation (14) if the resonant frequency of the resonator is lower than a desired value specified for the device (1).

4. The method according to claim 3,
wherein material in the resonance region (15) is removed as a result of the irradiation with electromagnetic radiation (14) and deposits uniformly on the entire surface of the component (2), such that the thickness of the resonator is reduced in the resonance region.

5. The method according to any of the preceding claims,
wherein the MEMS component (2) has a resonator having a resonance region (15), which determines the acoustic properties of the resonator, and a passive region (16, 17), which does not directly determine the acoustic properties, wherein the passive region (16, 17) of the resonator is irradiated with electromagnetic radiation (14) if the resonant frequency of the resonator is higher than a desired value specified for the device (1).

6. The method according to claim 5,
wherein material in the passive region (16, 17) is removed as a result of the irradiation with electromagnetic radiation (14) and deposits uniformly on the entire surface of the component (2), such that the thickness of the resonator is increased in the resonance region (15).

7. The method according to any of the preceding claims,
wherein the component (2) is encapsulated in a gas atmosphere, wherein the material of the surface of the component (2) is heated as a result of the irradiation with electromagnetic radiation (14) and combines with the gas atoms of the gas atmosphere.

8. The method according to claim 7,
wherein the gas reacts with the surface and modifies the latter, or
wherein the irradiating brings about a deposition of the gas molecules on the surface.

9. The method according to any of the preceding claims,
comprising the following steps:
encapsulating the component (2) in an atmosphere comprising N₂, and
trimming the component (2) by reactive nitriding of the surface of the component (2) by irradiating with the electromagnetic radiation (14).

10. The method according to any of the preceding claims,
comprising the following steps:
encapsulating the component (2) in an oxygen atmosphere, and
trimming the component (2) by oxidizing the surface of the component (2) by irradiating with the electromagnetic radiation (14).

11. The method according to any of the preceding claims,
comprising the following steps:
applying a trimming layer (9) on the surface of the component (2) prior to encapsulating, and
trimming the component (2) by increasing the density of the trimming layer (9) by irradiating with electromagnetic radiation (14).

12. The method according to any of the preceding claims,
wherein a femtosecond laser is used for irradiating the component (2).

13. The method according to any of the preceding claims,
wherein the component (2) has a resonator operating with surface acoustic waves and having a metallization in the form of a finger structure comprising electrode fingers (30), and
wherein the width of an electrode finger (30) is reduced as a result of the irradiation with electromagnetic radiation (14).

14. The method according to any of the preceding claims,
wherein a plurality of resonators are produced on the substrate (3) and are interconnected to form a duplexer, and
wherein the resonators are jointly encapsulated, wherein the resonators, after encapsulation, are successively trimmed by irradiation with electromagnetic radiation (14).

15. The method according to any of the preceding claims,
wherein the MEMS component (2) is encapsulated in a thin film package, the layer construction of which was produced directly on the substrate (3) using thin film methods.

16. An MEMS device (1) operating with acoustic waves, comprising
an MEMS component (2) on a substrate (3), and
a housing layer (10), which encapsulates the MEMS component (2) and which is transmissive to electromagnetic radiation (14) in a wavelength range.

17. The MEMS device (1) according to claim 16,
wherein the surface of the component (2) has at least one local region having an increased density that is higher than the density of the rest of the surface of the component (2).
